(19) United States
(12) Patent Application Publication
(10) Pub. No.: US 2020/0083085 A1
(43) Pub. Date: Mar. 12, 2020

(54) SUSCEPTOR AND CHEMICAL VAPOR DEPOSITION APPARATUS

(71) Applicant: SHOWA DENKO K.K., Tokyo (JP)

(72) Inventors: Jia YU, Yokohama-shi (JP); Naoto ISHIBASHI, Chichibu-shi (JP); Keisuke FUKADA, Chichibu-shi (JP); Yoshikazu UMETA, Chichibu-shi (JP); Hironori ATSUMI, Chichibu-shi (JP)

(73) Assignee: SHOWA DENKO K.K., Tokyo (JP)

(21) Appl. No.: 16/559,844

(22) Filed: Sep. 4, 2019

(30) Foreign Application Priority Data
Sep. 6, 2018 (JP) 2018-167035

(51) Int. Cl. H01L 21/687; C23C 16/458; H01L 21/02

(52) U.S. Cl. CPC H01L 21/6875; C30B 25/12; H01L 21/02293; C23C 16/4588

(57) ABSTRACT

A susceptor which is used in a chemical vapor deposition apparatus for growing an epitaxial layer on a principal plane of a wafer by a chemical vapor deposition method, and which includes a base; and three protrusion parts that are disposed on an outer circumferential part of the base and support an outer circumferential part of the wafer, is provided.

### BACKGROUND OF THE INVENTION

### Field of the Invention

The present invention relates to a susceptor and a chemical vapor deposition apparatus.

Priority is claimed on Japanese Patent Application No. 2018-167035, filed Sep. 6, 2018, the content of which is incorporated herein by reference.

### Description of Related Art

Silicon carbide (SiC) has a dielectric breakdown electric field which is one digit larger, and has three times the band gap and about three times the thermal conductivity as compared with silicon (Si). Since silicon carbide has these characteristics, it is expected to be applied to power devices, high frequency devices, high-temperature operation devices, and the like. For this reason, in recent years, a SiC epitaxial wafer has come to be used for the above-described semiconductor devices.

The SiC epitaxial wafer is manufactured by growing a SiC epitaxial layer, which becomes an active region of a SiC semiconductor device, on a SiC substrate (a SiC wafer, a wafer). The SiC wafer is obtained by processing from a bulk single crystal of SiC produced by a sublimation method or the like, and the SiC epitaxial layer is formed by a chemical vapor deposition (CVD) apparatus.

As an example of a CVD apparatus, there is an apparatus having a susceptor (a wafer support) rotating around a rotation axis. By rotating a wafer placed on the susceptor, a gas supply state becomes uniform in an in-plane direction, and thereby a uniform epitaxial layer can be grown on the wafer. The wafer is transported to the inside of the CVD apparatus manually or using automatic transport mechanism, and disposed on the susceptor. The susceptor on which the wafer is placed is heated from a back side thereof, and a reaction gas is supplied to a surface of the wafer from above to perform film formation.

For example, Patent Documents 1 and 2 disclose an apparatus having a susceptor (holder).

The susceptor disclosed in Patent Document 1 has substrate supporting parts, and side surface protruding parts that protrudes from an inner surface toward the center of the susceptor. The side surface protruding parts prevents a side surface of a substrate from coming into surface contact with the susceptor. Heat radiation is dominant in a central part of the substrate, and heat conduction is dominant in an outer circumferential part of the substrate. By adjusting the temperature distribution generated on the substrate due to heat radiation and heat conduction, in-plane temperature distribution of the substrate becomes uniform.

In addition, a holder disclosed in Patent Document 2 has a protruding part at a portion on which a wafer is placed. The protruding part forms a space between the holder and the wafer, and prevents adhesion of the holder and the wafer.

### PATENT DOCUMENTS

[Patent Document 1] Japanese Unexamined Patent Application, First Publication No. 2009-88088

[Patent Document 2] Japanese Unexamined Patent Application, First Publication No. 2009-267422

### SUMMARY OF THE INVENTION

In the case of growing an epitaxial layer on a SiC wafer, a film-forming temperature is close to 1600° C. In the susceptors (holders) disclosed in Patent Documents 1 and 2, in-plane temperature distribution of the wafer can not be made sufficiently uniform in a high-temperature environment in which a SiC epitaxial layer is formed.

For example, in the susceptor disclosed in Patent Document 1, the substrate supporting parts are formed along an outer circumference. The wafer is supported by the substrate supporting parts, and an outer circumference of the wafer is in total surface contact with the substrate supporting parts. At a portion in contact with the substrate supporting part, a temperature changes locally due to heat conduction. In a film-forming environment, the susceptor often reaches higher temperatures, and around the any of the substrate supporting parts, a temperature becomes locally high.

The present invention has been made in view of the above problems, and the invention provides a susceptor and a chemical vapor deposition apparatus by which uniformity of a wafer-in-plane carrier concentration of an epitaxial layer formed on a wafer can be improved.

As a result of earnest examination, the inventors of the present invention have found that uniformity of a wafer-in-plane carrier concentration of an epitaxial layer is improved by limiting parts supporting a wafer to three points.

In other words, the present invention provides the following procedures to solve the above problem.

(1) A susceptor according to a first embodiment is used in a chemical vapor deposition apparatus for growing an epitaxial layer on a principal plane of a wafer by a chemical vapor deposition method, and includes a base; and three protrusion parts that are disposed on an outer circumferential part of the base and support an outer circumferential part of the wafer.

(2) In the susceptor according to the above embodiment, the base may have a circular concave part, and an annular outer part that is vertically in contact with an outer circumference of the circular concave part; and the three protrusion parts may be disposed on the annular outer part.

(3) In the susceptor according to the above embodiment, a height of a first end of the three protrusion parts relative to the circular concave part may be 1 mm to 5 mm.

(4) In the susceptor according to the above embodiment, the three protrusion parts may be concentrically arranged.

(5) In the susceptor according to the above embodiment, the three protrusion parts may be arranged at equal intervals.

(6) In the susceptor according to the above embodiment, when the wafer is placed, the three protrusion parts may be disposed at locations other than an orientation flat part of the wafer.

(7) In the susceptor according to the above embodiment, a height of each of the three protrusion parts may be 0.1 mm to 5 mm.

(8) In the susceptor according to the above embodiment, a shape of the three protrusion parts may be an upwardly projecting hemisphere.

(9) In the susceptor according to the above embodiment, a shape of the three protrusion parts is an upwardly projecting cone.

(10) In the susceptor according to the above embodiment, a holding ring may be further comprised in an outer circumferential direction of the protrusion part on the annular outer part

(11) A chemical vapor deposition apparatus according to a second embodiment includes the susceptor according to the above embodiment.

According to the susceptor and the chemical vapor deposition apparatus according to one embodiment of the present invention, it is possible to improve uniformity of a wafer-in-plane carrier concentration of an epitaxial layer formed on a wafer.

### BRIEF DESCRIPTION OF THE DRAWINGS

FIG. 1 is a schematic cross-sectional view of a chemical vapor deposition apparatus according to a first embodiment.

FIG. 2 is a plan view of a susceptor of the chemical vapor deposition apparatus according to the first embodiment.

FIG. 3 is a cross-sectional view of the susceptor of the chemical vapor deposition apparatus according to the first embodiment.

FIG. 4 is a cross-sectional view of another example of a susceptor of the chemical vapor deposition apparatus according to the first embodiment.

FIG. 5A is a cross-sectional view of still another example of a susceptor of the chemical vapor deposition apparatus according to the first embodiment.

FIG. 5B is a cross-sectional view of still another example of a susceptor of the chemical vapor deposition apparatus according to the first embodiment.

FIG. 6 is a cross-sectional view of a modification example of a susceptor of the chemical vapor deposition apparatus according to the first embodiment.

FIG. 7 is a result of measuring in-plane distribution of a growth rate of an epitaxial layer in Example 1.

FIG. 8 is a result of measuring in-plane distribution of a carrier concentration of the epitaxial layer in Example 1.

FIG. 9 is a result of measuring in-plane distribution of a growth rate of an epitaxial layer in Comparative Example 1.

FIG. 10 is a result of measuring in-plane distribution of a carrier concentration of the epitaxial layer in Comparative Example 1.

### DETAILED DESCRIPTION OF THE INVENTION

Hereinafter, preferable examples of a susceptor and a chemical vapor deposition apparatus according to one embodiment of the present invention will be described in detail with reference to the drawings as appropriate. In the drawings used in the following description, characteristic parts are shown in an enlarged manner in some cases for the sake of convenience in order to make the features of the present invention easy to understand, and dimensional ratios and the like between the components may be different from actual ratios. Materials, dimensions, and the like in the following description are merely exemplary examples, and the present invention is not limited thereto. For example, the numbers, numerical values, quantities, ratios, characteristics, and the like can be appropriately omitted, added, or changed without departing from the spirit of the present invention.

Chemical Vapor Deposition Apparatus

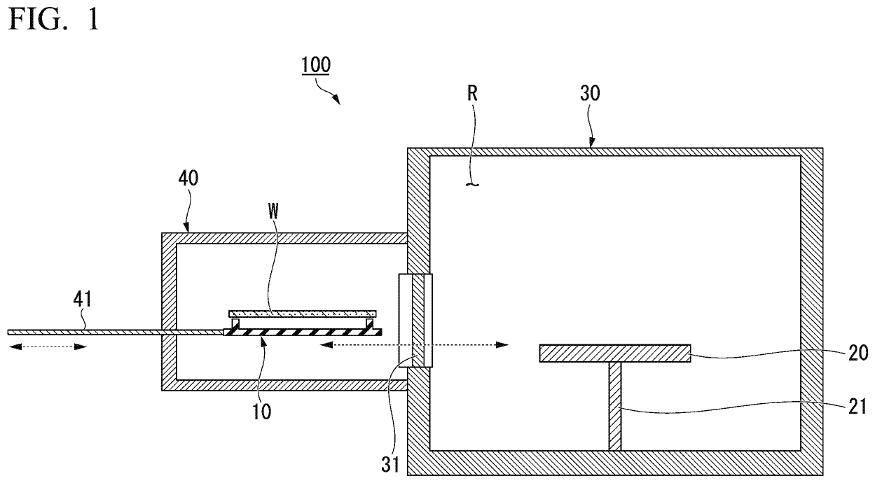

FIG. 1 is an example of a schematic cross-sectional view of a chemical vapor deposition apparatus according to a first embodiment. The chemical vapor deposition apparatus 100 according to the first embodiment includes a furnace body 30, a preparation chamber 40, and a susceptor 10 moving back and forth between the furnace body 30 and the preparation chamber 40. In FIG. 1, a wafer W is shown together for the convenience of easy understanding.

The furnace body 30 forms a film formation space R. The film formation space R is a space for growing an epitaxial layer (epitaxial film) on the wafer. Hereinafter, in the present specification, growing the epitaxial layer on a principal plane of the wafer may be referred to as “film formation.” The film formation space R has a high temperature of about 1600° C. during film formation.

Inside the furnace body 30, a support 20 and a pillar 21 are provided. The support 20 supports the susceptor 10 in the film formation space R. The support 20 is supported by the pillar 21. The pillar 21 shown in FIG. 1 supports the center of the support 20. The pillar 21 may support an outer circumference of the support 20. At least one of the support 20 and the pillar 21 may be rotatable. In the present specification, a film formation surface side of the wafer W may be called an upper side, and the side opposite to the film formation surface may be called a lower side. The susceptor 10 and the wafer W placed on the support 20 are heated by a heater (not shown).

A gas supply pipe (not shown) is installed in the furnace body 30. The gas supply pipe supplies a source gas, a carrier gas, an etching gas, and the like to the film formation space R. The furnace body 30 has a shutter 31. The shutter 31 is located between the furnace body 30 and the preparation chamber 40. The shutter 31 is opened when the susceptor 10 is transported to the film formation space R, and the shutter 31 is closed except during transportation. By closing the shutter 31, it is possible to prevent a gas from flowing out from the film formation space R at the time of film formation, and prevent the film formation space R from reaching a low temperature.

The preparation chamber 40 is adjacent to the furnace body 30 via the shutter 31.

The preparation chamber 40 has an arm 41. A first end part of the arm 41 is exposed outside the preparation chamber 40, and a second end part supports the susceptor 10. The arm 41 is a jig for transporting the susceptor 10 to the inside of the furnace body 30.

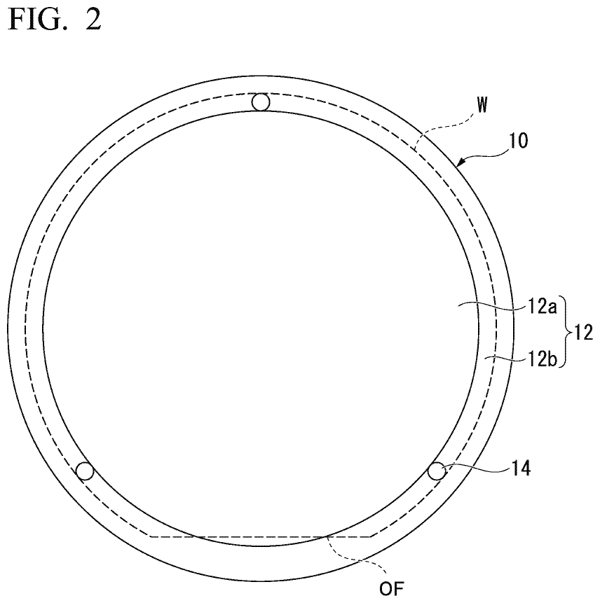

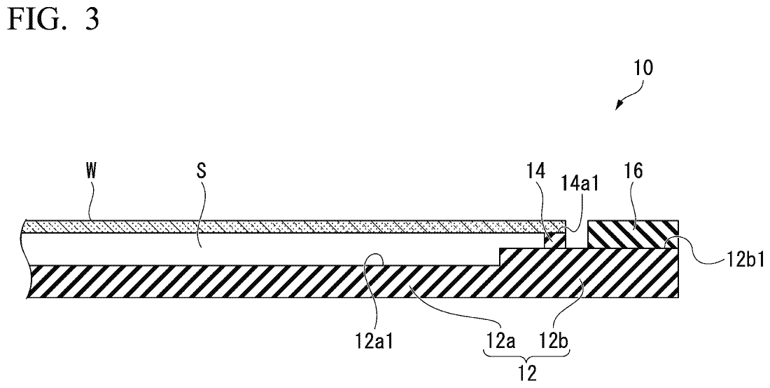

FIG. 2 is a plan view of an example of a susceptor of the chemical vapor deposition apparatus according to the first embodiment. FIG. 3 is a cross-sectional view of the susceptor of the chemical vapor deposition apparatus according to the first embodiment. The susceptor 10 shown in FIG. 2 has a base 12, a protrusion part 14, and a holding ring 16. In the chemical vapor deposition apparatus shown in FIGS. 2 and 3, the wafer W is shown together. The protrusion part 14 is a projection that the susceptor 10 has.

The base 12 shown in FIGS. 2 and 3 has a circular concave part 12a and an annular outer part 12b. The circular concave part 12a is a part surrounded by the annular outer part 12b among parts of the base 12 in a plan view. The annular outer part 12b has an annular circumferential shape in a plan view. The annular outer part 12b is a part projecting from a first surface 12a1 of the circular concave part 12a along a circumference. The annular outer part 12b is vertically in contact with an outer circumference of the circular concave part 12a. In other words, the circular concave part 12a and the annular outer part 12b are perpendicular to each other. The circular concave part 12a and the outer circumferential part 12b are not strictly circular in a plan view. For example, the circular concave part 12a and the outer circumferential part 12b may be partially straight or angular.

The circular concave part 12a may be regarded as a bottom part of the base 12. In addition, the annular outer part 12b may be regarded as an outer wall of the circular concave part 12a.

The first surface 12a1 of the circular concave part 12a is located below a first surface 12b1 of the annular outer part 12b. A height from the first surface 12a1 of the circular concave part 12a to the annular outer part 12b is preferably, for example, 1 mm to 5 mm, is more preferably 1.5 mm to 4.5 mm, and is even more preferably 2.5 mm to 3.5 mm.

A space S is formed between the wafer W and the circular concave part 12a. In the susceptor 10 according to the present embodiment, the space S between the susceptor and the wafer is widened by providing the circular concave part 12a, as compared with susceptors not having the circular concave part 12a. A case in which the space S can be widened is advantageous in that contact between the wafer W and the susceptor 10 can be avoided even in a case where the wafer W is curved.

By providing the annular outer part 12b on the susceptor 10, a distance from the wafer W to the first surface 12b1 of the annular outer part 12b of the susceptor 10, and a distance from the wafer W to the first surface 12a1 of the circular concave part 12a of the susceptor 10 shows different value. According to this configuration, at the same time, it is possible to obtain an effect of suppressing a film formation gas (deposition gas) from flowing around to a back surface of the wafer W more than necessary, and an effect of avoiding contact between the wafer W and the susceptor 10. The effect of suppressing a film formation gas from flowing around to a back surface of the wafer W more than necessary is associated with the configuration of shortening a distance from the wafer W to the first surface 12b1 of the annular outer part 12b. The effect of avoiding contact between the wafer W and the susceptor 10 is associated with the configuration of lengthening a distance from the wafer W to the first surface 12a1 of the circular concave part 12a of the susceptor 10.

The protrusion parts 14 support an outer circumferential part of the wafer W. The outer circumferential part of the wafer W is an area of 5% in an in-plane direction of a wafer diameter from an outer circumference end of the wafer. Accordingly, the outer circumferential part located at a position away from the center in the in-plane direction of the wafer. For example, in a case where a size of the wafer is 6 inches, the outer circumferential part is, for example, an area within a range of 0 mm to 7.5 mm from the outer circumference end.

The protrusion parts 14 shown in FIG. 2 support the outer circumference end of the wafer W to be placed. When the temperature of the wafer W is raised to a film-forming temperature, warpage occurs in the wafer W. Warpage occurs toward the susceptor, and the wafer W is curved in a protruding shape toward the susceptor 10. When the protrusion parts 14 support the outer circumference end of the wafer W, the wafer W is curved downward starting from the outer circumference end of the wafer W. The outer circumference end of the wafer W does not protrude above the protrusion parts 14. Accordingly, even in a case where the wafer W is warped, the outer circumference end of the wafer W can be held by the holding ring 16. Positional deviation of the wafer W is limited, and quality of the epitaxial layer can be improved.

There are three protrusion parts 14. As shown in FIG. 2, the wafer W is supported at three points by the protrusion parts 14.

The three protrusion parts 14 are the minimum number required to support the wafer W. By supporting the wafer W by the three protrusion parts 14, contact points between the wafer W and the susceptor 10 are reduced.

As shown in FIG. 3, the three protrusion parts 14 are disposed on the annular outer part 12b. When the protrusion parts 14 are provided on the annular outer part 12b, the space S between the wafer W and the susceptor 10 is widened.

As described above, when a temperature of the wafer W is raised to a film-forming temperature, warpage occurs in the wafer W. Since the space S is present between the wafer W and the susceptor 10, contact between the wafer W and the susceptor 10 can be avoided even in a case where the wafer W is curved.

The height of each of the three protrusion parts 14 is preferably 0.1 mm to 5 mm, is more preferably 0.2 mm to 3 mm, and is even more preferably 0.3 mm to 1 mm. A low height of the protrusion part 14 increases a possibility of the susceptor 10 contacting the wafer W at an unintended part. A high height of the protrusion 14 increases a possibility of a source gas or the like flowing around to the back surface of the wafer W.

The height of a first end 14a1 of the three protrusion parts 14 relative to the first surface 12a1 of the circular concave part 12a is preferably 1 mm to 5 mm, and is more preferably 2 mm to 3 mm. Accordingly, a distance of the back surface of the wafer W and the first surface of 12a1 of the circular concave part 12a is preferably 1 mm to 5 mm when the wafer W is placed. When the height is within this range, the space S is sufficiently secured.

The three protrusion parts 14 shown in FIG. 2 are concentrically arranged. In addition, the three protrusion parts 14 are arranged at equal intervals. Arrangement of the protrusion parts 14 is not limited to that shown in FIG. 2, but when the protrusion parts are arranged in the above-described manner, stability of the wafer W to be placed thereon is improved.

In a case where the wafer W is placed, the three protrusion parts 14 are preferably arranged at a position other than that of an orientation flat OF of the wafer W, and one protrusion part 14 of the three protrusion parts 14 is preferably located at a position facing the orientation flat OF of the wafer W to be placed. The orientation flat OF is a notch provided in the wafer W, and is an index for, for example, a crystal orientation of a crystal forming the wafer W. The orientation flat OF is a part having a different shape of the outer circumferential part of the wafer, and a heat transfer manner in this part easily varies from other parts of the outer circumferential part of the wafer. When one protrusion part 14 out of the three protrusion parts 14 serving as substrate supporting parts overlaps this position, holding the wafer concentrically and uniformly becomes difficult. In addition, when one protrusion part 14 out of the three protrusion parts serving as the substrate supporting parts overlaps the orientation flat OF, it may be difficult to maintain temperature uniformity. Heat is transferred via the protrusion parts 14. Heat uniformity of the wafer W can be improved by providing the protrusion parts 14 at positions away from the orientation flat OF where temperature uniformity easily deteriorates. Arranging the protrusion parts 14 at positions facing the orientation flat OF is preferable because then the orientation flat OF and the protrusion parts 14 are most separated from each other.

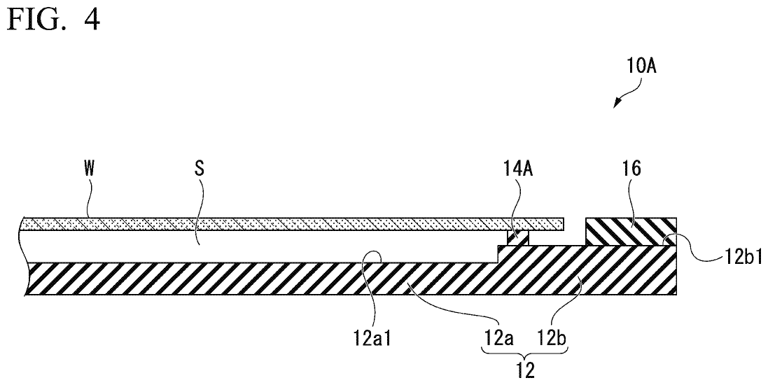

FIG. 4 is a cross-sectional view of another example of a susceptor of the chemical vapor deposition apparatus according to the first embodiment. A susceptor 10A shown in FIG. 4 is different from the susceptor 10 shown in FIG. 2 in a position of a protrusion part 14A. The rest of the configuration is the same.

The protrusion part 14A of the susceptor 10A shown in FIG. 4 is provided to be located at an inner side in an in-plane direction of the outer circumference end of the wafer W to be placed. As long as the protrusion part 14A is inside the outer circumference end of the wafer W, the arrangement can be arbitrarily selected since the effect of improving temperature uniformity can be obtained by reducing a contact area between the susceptor 10A and the wafer W.

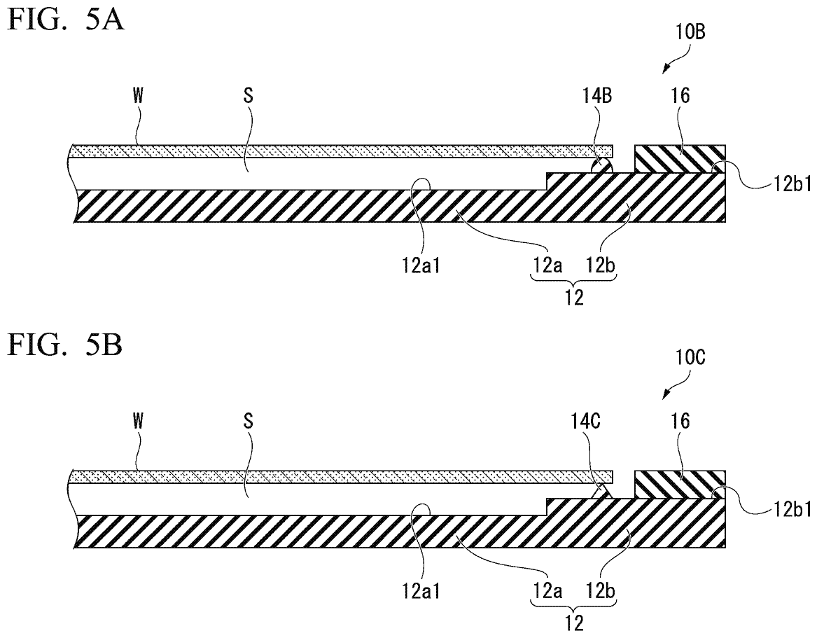

In addition, FIGS. 5A and 5B are cross-sectional views of still another example of a susceptor of the chemical vapor deposition apparatus according to the first embodiment. Susceptors 10B and 10C shown in FIGS. 5A and 5B are different from the susceptor 10 shown in FIG. 2 in a shape of protrusion parts 14B and 14C. The rest of the configuration is the same.

The protrusion part 14B of the susceptor 10B shown in FIG. 5A is an upwardly projecting hemisphere shape. In other words, a shape of the protrusion part 14B is a hemisphere. The protrusion part 14C of the susceptor 10C shown in FIG. 5B is conical shape having a distal end. In other words, a shape of the protrusion part 14C is conical. This is a configuration in which a contact area between the protrusion parts 14B and 14C, and the wafer W is small (a point contact), and heat conduction from the protrusion parts 14B and 14C can be further limited.

The shape of the protrusion parts is not limited to the above shapes. For example, a shape may be a triangular pyramidal shape, a square pyramidal shape, or the like. The shape of the protrusion is preferably tapered.

Graphite, SiC, Ta, Mo, W, or the like can be used for the susceptors 10, 10A, 10B, and 10C. In addition to these solid materials, a surface may be coated with a metal carbide such as SiC or TaC. For example, graphite or TaC-coated graphite is used as the susceptors 10, 10A, 10B, and 10C.

The holding ring 16 is located on the side of the wafer W. For example, the holding ring 16 is located in an outer circumference direction of the protrusion parts on the first surface 12b1 of the annular outer part 12b of the wafer. The holding ring 16 prevents deviation of the wafer W. The holding ring 16 may be a separate member separated from the susceptor 10 or may be integrated therewith.

The holding ring 16 covers the outer circumference of the wafer W. The holding ring 16 prevents the gas from flowing around to the back surface of the wafer W. The wafer W shown in FIGS. 2 and 3 is supported by three protrusion parts 14, and other parts not supported thereby have a gap between the wafer W and the susceptor 10. Because the holding ring 16 is on the other side of the gap, flow of gas around the back surface of the wafer can be sufficiently limited even when the number of the protrusion parts 14 is small.

As described above, the chemical vapor deposition apparatus according to the first embodiment includes the susceptor 10 having the three protrusion parts 14. The wafer W is supported by the three protrusion parts 14. Accordingly, a contact area between the wafer W and the protrusion parts 14 is reduced. For example, in a case of forming an epitaxial layer of SiC, its temperature becomes close to 1600° C. The wafer W is heated by radiation, and heat is dissipated from the protrusion parts 14 due to heat conduction. By reducing the contact area between the wafer W and the protrusion parts 14 where heat radiation occurs, heat distribution in an in-plane direction of the wafer W can be reduced at the time of film formation. The density of a carrier doped to the epitaxial layer is affected by a film-forming temperature. By reducing the heat distribution in the in-plane direction of the wafer W, uniformity of a carrier concentration in the in-plane direction of the wafer W is improved.

Although the preferred embodiments of the present invention have been described in detail above, the present invention is not limited to specific embodiments. Various modifications and changes can be made and appropriately combined to conduct the present invention, within the scope of the present invention described in the claims.

### MODIFICATION EXAMPLE

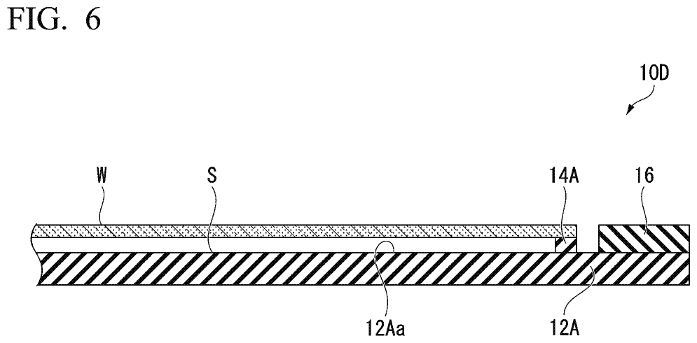

FIG. 6 is a schematic cross-sectional view of a modification example of a susceptor of the chemical vapor deposition apparatus according to the first embodiment. In a susceptor 10D according to the modification example, a shape of a base 12A is different from the shape of the base 12 shown in FIG. 3. The rest of the configuration is the same, and therefore a description thereof will be omitted.

The base 12A shown in FIG. 6 has a first surface 12Aa that is a flat surface, and does not have a circular concave part. A protrusion part 14A protrudes from the base 12A at a position that is the outer circumferential part of the wafer W to be placed. Also in the susceptor 10D according to the modification example, a contact area between the wafer W and the protrusion part 14A is small. Accordingly, according to the susceptor 10D according to the modification example, heat distribution in the in-plane direction of the wafer W during film formation can be reduced, and uniformity of a carrier concentration in the in-plane direction of the wafer W can be improved.

### EXAMPLES

### Example 1

As shown in FIG. 2 and FIG. 3, the susceptor 10 having the three protrusion parts 14 was prepared. A shape of the protrusion parts 14 was made into a rectangular parallelepiped having a square shape in a plan view. One side of the square was 3 mm, and the height of the protrusion part was 0.3 mm. The protrusion parts 14 were concentrically arranged. Designing was performed such that the center of the protrusion parts 14 was located at a position separated by 0.8 mm from the outer circumference end of the wafer W. One protrusion part 14 of the three protrusion parts 14 was provided at a position facing the orientation flat OF. The remaining protrusion parts were provided at positions rotated by 120° from the reference protrusion part 14. The wafer W was a SiC wafer having a diameter of 150 mm.

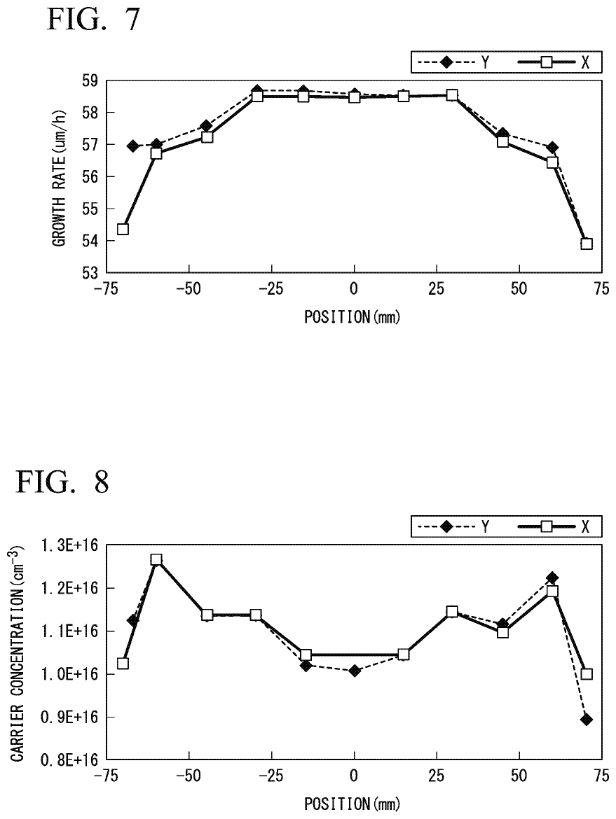

An epitaxial layer of SiC was grown on the SiC wafer. A growth rate of the epitaxial layer and a carrier concentration of the epitaxial layer were measured. The results are shown in FIG. 7 and FIG. 8.

FIG. 7 is a result of measuring in-plane distribution of a growth rate of an epitaxial layer in Example 1. FIG. 8 is a result of measuring in-plane distribution of a carrier concentration of the epitaxial layer in Example 1. The measurements in FIG. 7 and FIG. 8 were performed along two orthogonal directions passing through the center on a principal plane of the SiC epitaxial wafer.

### Comparative Example 1

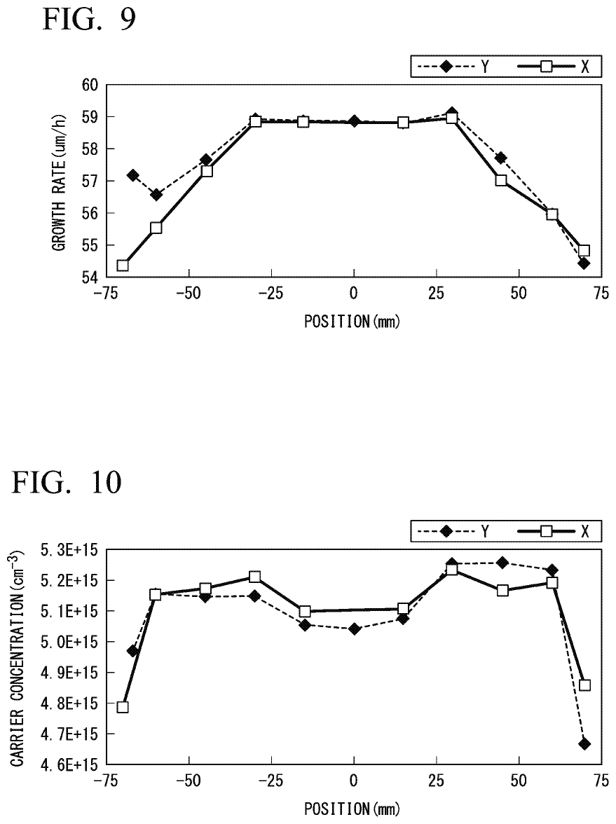

Comparative Example 1 differs from Example 1 in that protrusion parts are provided in an annular shape. The wafer W was supported by annular protrusion parts formed along an outer circumference. The other points were the same as in Example 1, and a growth rate of the epitaxial layer and a carrier concentration of the epitaxial layer were measured. The results are shown in FIG. 9 and FIG. 10. FIG. 9 is a result of measuring in-plane distribution of a growth rate of an epitaxial layer in Comparative Example 1. FIG. 10 is a result of measuring in-plane distribution of a carrier concentration of the epitaxial layer in Comparative Example 1. The measurements in FIG. 9 and FIG. 10 were performed along two orthogonal directions passing through the center on a principal plane of the SiC epitaxial wafer.

Comparing the graphs of FIG. 7 and FIG. 9, significant difference was not seen in the growth rate of the epitaxial layer between the case of using the susceptor of Example 1 and the case of using the susceptor of Comparative Example 1. As shown in FIG. 7, in a case where the susceptor of Example 1 was used, the in-plane distribution of the growth rate was 7.6%. In regard to this value, as shown in FIG. 9, in a case where the susceptor of Comparative Example 1 was used, the in-plane distribution of the growth rate was 7.5%. The in-plane distribution of the growth rate is obtained by dividing a difference between a growth rate at a position where a growth rate is the fastest, and a growth rate at a position where a growth rate is slowest, by the average value of in-plane growth rates.

Meanwhile, when the graphs of FIG. 8 and FIG. 10 are compared, a difference occurs in uniformity of a carrier concentration of the epitaxial layer between the case of using the susceptor of Example 1 and the case of using the susceptor of Comparative Example 1. The uniformity of the carrier concentration was higher in Example 1 than in Comparative Example 1. As shown in FIG. 8, in a case where the susceptor of Example 1 was used, the in-plane distribution of the carrier concentration was 6.1%. In regard to this value, as shown in FIG. 10, in a case where the susceptor of Comparative Example 1 was used, the in-plane distribution of the carrier concentration was 11.6%. The in-plane distribution of the carrier concentration is obtained by dividing a difference between a carrier concentration at a position where a carrier concentration is the highest, and a carrier concentration at a position where a carrier concentration is lowest, by the average value of in-plane carrier concentrations.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

10, 10A, 10B, 10C, 10D Susceptor
12 Base
12a Circular concave part
12b Annular outer part
14, 14A, 14B, 14C Protrusion part
16 Holding ring
20 Support
21 Pillar
30 Furnace body
31 Shutter
40 Preparation chamber
41 Arm
100 Chemical vapor deposition apparatus
OF Orientation flat
R Film formation space (deposition space)
S Space
W Wafer

What is claimed is:

1. A susceptor which is used in a chemical vapor deposition apparatus for growing an epitaxial layer on a principal plane of a wafer by a chemical vapor deposition method, the susceptor comprising:
a base; and
three protrusion parts that are disposed on an outer circumferential part of the base and support an outer circumferential part of the wafer.

2. The susceptor according to claim 1,
wherein the base includes a circular concave part, and an annular outer part that is vertically in contact with an outer circumference of the circular concave part, and
the three protrusion parts are disposed on the annular outer part.

3. The susceptor according to claim 1, wherein a height of a first end of the three protrusion parts relative to the circular concave part is placed is 1 mm to 5 mm.

4. The susceptor according to claim 1, wherein the three protrusion parts are concentrically arranged.

5. The susceptor according to claim 4, wherein the three protrusion parts are arranged at equal intervals.

6. The susceptor according to claim 1, wherein, when the wafer is placed, the three protrusion parts are disposed at locations other than an orientation flat part of the wafer.

7. The susceptor according to claim 1, wherein a height of each of the three protrusion parts is 0.1 mm to 5 mm.

8. The susceptor according to claim 1, wherein a shape of the three protrusion parts is an upwardly projecting hemisphere.

9. The susceptor according to claim 1, wherein a shape of the three protrusion parts is an upwardly projecting cone.

10. The susceptor according to claim 1, further comprising a holding ring in an outer circumferential direction of the protrusion part on the annular outer part.

11. A chemical vapor deposition apparatus comprising the susceptor according to claim 1.
